(19) United States
(12) Patent Application Publication
(10) Pub. No.: US 2013/0299776 A1
(43) Pub. Date: Nov. 14, 2013

(54) HIGH OUTPUT POWER, HIGH EFFICIENCY BLUE LIGHT-EMITTING DIODES

(71) Applicant: THE REGENTS OF THE UNIVESITY OF CALIFORNIA, Oakland, CA (US)

(72) Inventors: Shuji Nakamura, Santa Barbara, CA (US); Steven P. DenBaars, Goleta, CA (US); Daniel F. Feezell, Albuquerque, NM (US); James S. Speck, Goleta, CA (US); Chih-Chien Pan, Goleta, CA (US); Shinichi Tanaka, Santa Barbara, CA (US)

(73) Assignee: The Regents of the University of California, Oakland, CA (US)

(21) Appl. No.: 13/890,599

(22) Filed: May 9, 2013

Related U.S. Application Data
(60) Provisional application No. 61/644,803, filed on May 9, 2012.

(51) Int. Cl. H01L 33/32; H01L 33/00; H01L 33/16; H01L 33/04

(52) U.S. Cl. CPC H01L 33/32; H01L 33/04; H01L 33/0075; H01L 33/16
USPC 257/13; 438/46

(57) ABSTRACT

A III-nitride based semipolar LED with a light output power of at least 100 milliwatts (mW), or with an External Quantum Efficiency (EQE) of at least 50%, for a current density of at least 100 Amps per centimeter square (A/cm²).

### CROSS REFERENCE TO RELATED APPLICATIONS

This application claims priority under 35 U.S.C. §119(e) of the following co-pending and commonly-assigned U.S. Provisional Patent Application:

U.S. Provisional Patent Application Ser. No. 61/644,803, entitled “HIGH OUTPUT POWER, HIGH EFFICIENCY BLUE LIGHT-EMITTING DIODES,” filed on May 9, 2012, by Shuji Nakamura, Steven P. DenBaars, Daniel Feezell, James S. Speck, Chih-Chien Pan, and Shinichi Tanaka, attorney's docket number 30794.452.US-P1 (UC docket no. 2012-735-1), which application is incorporated by reference herein.

This application is related to the following co-pending and commonly-assigned U.S. patent applications:

U.S. Utility Application Ser. No. 61/644,808, filed on same date herewith, by Shuji Nakamura, Steven P. DenBaars, Daniel Feezell, James S. Speck, and Chih-Chien Pan, entitled “LIGHT-EMITTING DIODES WITH LOW TEMPERATURE DEPENDENCE,” attorneys' docket number 30794.453-US-U1 (2012-736-2), which application claims priority under 35 U.S.C. §119(e) of U.S. Provisional Application Ser. No. ______, filed on May 9, 2012, by Shuji Nakamura, Steven P. DenBaars, Daniel Feezell, James S. Speck, and Chih-Chien Pan, entitled “LIGHT-EMITTING DIODES WITH LOW TEMPERATURE DEPENDENCE,” attorneys' docket number 30794.453-US-P1 (2012-736-1);

U.S. Utility application Ser. No 12/001,227, filed on Dec. 11, 2007, now U.S. Patent Publication No. 2008/0179607, published on Jul. 31, 2008, by Steven P. DenBaars, Mathew C. Schmidt, Kwang Choong Kim, James S. Speck, and Shuji Nakamura, entitled “NON-POLAR (M-PLANE) AND SEMI-POLAR EMITTING DEVICES,” attorneys' docket number 30794.213-US-U1 (2007-317-1), which application claims the benefit under 35 U.S.C. Section 119(e) of U.S. Provisional Application Ser. No. 60/869,540, filed on Dec. 11, 2006, by Steven P. DenBaars, Mathew C. Schmidt, Kwang Choong Kim, James S. Speck, and Shuji Nakamura, entitled “NON-POLAR (M-PLANE) AND SEMI-POLAR EMITTING DEVICES,” attorneys' docket number 30794.213-US-P1 (2007-317-1); and

U.S. Utility application Ser. No. 13/300,977, filed on Nov. 21, 2011, by Roy B. Chung, Zhen Chen, James S. Speck, Steven P. DenBaars, and Shuji Nakamura, entitled “OPTOELECTRONIC DEVICE BASED ON NON-POLAR AND SEMI-POLAR ALUMINUM INDIUM NITRIDE AND ALUMINUM INDIUM GALLIUM NITRIDE ALLOYS,” attorney's docket number 30794.294-US-C1 (2009-258), which application is a continuation of and claims the benefit under 35 U.S.C. Section 120 of U.S. Utility application Ser. No. 12/610,945, filed on Nov. 2, 2009, now U.S. Pat. No. 8,084,763, issued Dec. 27, 2011, by Roy B. Chung, Zhen Chen, James S. Speck, Steven P. DenBaars, and Shuji Nakamura, entitled “OPTOELECTRONIC DEVICE BASED ON NON-POLAR AND SEMI-POLAR ALUMINUM INDIUM NITRIDE AND ALUMINUM INDIUM GALLIUM NITRIDE ALLOYS,” attorney's docket number 30794.294-US-U1 (2009-258), which application claims the benefit under 35 U.S.C. Section 119(e) of U.S. Provisional Application Ser. No. 61/110,449, filed on Oct. 31, 2008, by Roy B. Chung, Zhen Chen, James S. Speck, Steven P. DenBaars, and Shuji Nakamura, entitled “OPTOELECTRONIC DEVICE BASED ON NON-POLAR AND SEMI-POLAR ALUMINUM INDIUM NITRIDE AND ALUMINUM INDIUM GALLIUM NITRIDE ALLOYS,” attorney's docket number 30794.294-US-P1 (2009-258); all of which applications are incorporated by reference herein.

### BACKGROUND OF THE INVENTION

1. Field of the Invention

This invention relates to high-output-power and high-efficiency light-emitting diodes (LEDs).

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Wide band-gap InGaN/GaN based light-emitting diodes (LEDs) have attracted considerable attention due to their use in general illumination, full-color displays, and mobile headlamps, and are often operated at high drive currents to achieve high emission powers. However, current commercial LEDs grown on the c-plane of the wurtzite crystal suffer from the Quantum Confined Stark Effect (QCSE) due to the large polarization-related electric fields. This effect causes band bending in the active region and results in the spatial separation of the electron and hole wave functions, thus lowering the internal quantum efficiency (IQE). Moreover, the IQE is further reduced with increasing injection current—a well-studied but controversial phenomenon known as “efficiency droop.”

### SUMMARY OF THE INVENTION

The present invention discloses high-output-power and high-efficiency light-emitting diodes (LEDs) or LED structures, e.g., semipolar III-nitride LEDs.

In one embodiment, the present invention discloses a III-nitride based LED, comprising a III-nitride based semipolar LED with a light output power of at least 100 milliwatts (mW), or with an External Quantum Efficiency (EQE) of at least 50%, at a current density of at least 100 Amps per centimeter square (A/cm²).

For example, an LED according to the present invention can have higher output power (e.g., LOP) and higher efficiency (e.g., EQE) than a c-plane polar (0001) LED with a similar structure. For example, the present invention can use a thick well in the semipolar LED structure by reducing polarization related electric fields, which is not the case for a c-plane polar LED.

The LEDs of the present invention can be grown on semipolar, free-standing, and/or bulk GaN, on a GaN substrate, or on a semipolar plane of the GaN (e.g., grown on a (20-2-1) semipolar plane of the GaN). The active region of LED structure, for emitting the light, can comprise one or more quantum wells or be a wide single quantum well (SQW), e.g., wherein a quantum well thickness is thicker than 4 nm. A peak wavelength of the LED light can be in the blue spectrum or wavelength range, e.g., wherein the wavelength shift of the peak wavelength can less than 4 nm up to a current density of 400 Amps per centimeter square (A/cm²). The size of the LED or LED chip can be less than 0.2 millimeters squared (mm²). A top surface area of the LED, a top surface area of the LED chip, a top surface area of the LED mesa, or a top surface of the light emitting active region of the LED, can be less than 0.2 mm².

The light output powers (LOPs) can be 140, 253, 361, and 460 milliwatts (mW) at current densities of 100, 200, 300, and 400 A/cm², respectively.

The output power can be more than 140 mW at the current density of 100 A/cm² or more than 460 mW at the current density of 400 A/cm².

The external quantum efficiencies can be 50.1, 45.3, 43.0, and 41.2% at current densities of 100, 200, 300, and 400 A/cm², respectively.

The EQE drop can be less than 9% when the current density is changed from 100 to 400 A/cm².

The LED can be grown on a semipolar plane of a GaN substrate and the LED has a crystal quality, active region thickness, semipolar orientation, and structure such that the light output power is at least 100 mW, or the EQE is at least 50%, at the current density of at least 100 A/cm².

The structure can increase carrier distribution uniformity in the active region, the active region thickness can reduce the carrier density, and the semipolar orientation of the LED can increase the crystal quality such that the output power or the EQE is obtained.

The structure can include a number of quantum wells in the active region.

The structure can include a superlattice between the substrate and an active region of the LED, wherein the superlattice has a number of periods and composition such that the light output power is at least 100 mW, or the EQE is at least 50%, for the current density of at least 100 A/cm².

The LED can further comprise a GaN substrate; an n-type GaN layer overlying a semipolar plane of the GaN substrate; the superlattice comprising an InGaN/GaN superlattice overlying the n-type GaN layer; the active region including an InGaN/GaN single quantum well overlying the InGaN/GaN superlattice; an AlGaN electron blocking layer overlying the single quantum well; a p-type GaN layer overlying the electron blocking layer; a transparent conductive contact layer overlying the p-type GaN layer; and metal contact to the n-type GaN layer.

The present invention further discloses a method of fabricating a device, comprising fabricating and growing a III-nitride based semipolar Light Emitting Diode (LED) having a light output power of at least 100 mW, or an EQE of at least 50%, at a current density of at least 100 A/cm².

### BRIEF DESCRIPTION OF THE DRAWINGS

Referring now to the drawings in which like reference numbers represent corresponding parts throughout:

FIG. 1(a) is a cross-sectional schematic of an LED structure of a blue LED grown on (20-2-1) free-standing Gallium Nitride (GaN).

FIG. 1(b) illustrates the LED of FIG. 1(a) on a vertical stand package.

FIG. 2(a) plots Light Output Power (LOP) and External Quantum Efficiency (EQE) of the semipolar (20-2-1) LED of FIG. 1(a)-(b) vs. current density, the inset is a semilog plot of EQE vs. current density, and FIG. 2(b) plots wall plug efficiency and forward voltage (V) as a function of current density for the LED of FIG. 1(a)-(b).

FIG. 3 plots Full Width at Half Maximum (FWHM) and peak wavelength for semipolar (20-2-1) GaN-based blue LED of FIG. 1(a)-(b) vs. current density.

FIG. 4 shows (a) a Micro-electroluminescence (μ-EL) image of the LED of FIGS. 1(a)-(b), (b) a Scanning Transmission Electron Microscope (STEM) image of the active area of the LED of FIGS. 1(a)-(b), and (c) μt-EL image of another area of the LED of FIG. 1(a)-(b).

FIG. 5 is a flowchart illustrating a method of fabricating an LED.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Nomenclature

The terms “(AlInGaN)” “(In,Al)GaN”, or “GaN” as used herein (as well as the terms “III-nitride,” “Group-III nitride”, or “nitride,” used generally) refer to any alloy composition of the (Ga,Al,In,B)N semiconductors having the formula Ga_{w}AlₓIn_{y}B_{z}N where 0≦w≦1, 0≦x≦1, 0≦y≦1, 0≦z≦1, and w+x+y+z=1. These terms are intended to be broadly construed to include respective nitrides of the single species, Ga, Al, In and B, as well as binary, ternary and quaternary compositions of such Group III metal species. Accordingly, it will be appreciated that the discussion of the invention hereinafter in reference to GaN and InGaN materials is applicable to the formation of various other (Ga,Al,In,B)N material species. Further, (Ga,Al,In,B)N materials within the scope of the invention may further include minor quantities of dopants and/or other impurity or inclusional materials.

Many (Ga,Al,In,B)N devices are grown along the polar c-plane of the crystal, although this results in an undesirable quantum-confined Stark effect (QCSE), due to the existence of strong piezoelectric and spontaneous polarizations. One approach to decreasing polarization effects in (Ga,Al,In,B)N devices is to grow the devices on nonpolar or semipolar planes of the crystal.

The term “nonpolar plane” includes the {11-20} planes, known collectively as a-planes, and the {10-10} planes, known collectively as m-planes. Such planes contain equal numbers of Group-III (e.g., gallium) and nitrogen atoms per plane and are charge-neutral. Subsequent nonpolar layers are equivalent to one another, so the bulk crystal will not be polarized along the growth direction.

The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

Technical Description

Semipolar (20-2-1) GaN-based devices are promising for high emission efficiency LEDs because they exhibit very little QCSE, hence increasing the radiative recombination rate due to an increase in the electron-hole wave function overlap. In addition, semipolar (20-2-1) blue LEDs also exhibit narrower Full Width at Half Maximum (FWHM) and less blue shift compared to commercial c-plane blue LEDs at different current densities, which could contribute to relatively high internal quantum efficiency because of reducing the band filling of localized states. Moreover, semipolar (20-2-1) blue LEDs can still maintain good performance by growing a quantum well thickness more than 4 nm without any degradation in crystal quality. Hence, the further reduction in the efficiency droop and electron overflow can be expected in semipolar (20-2-1) devices.

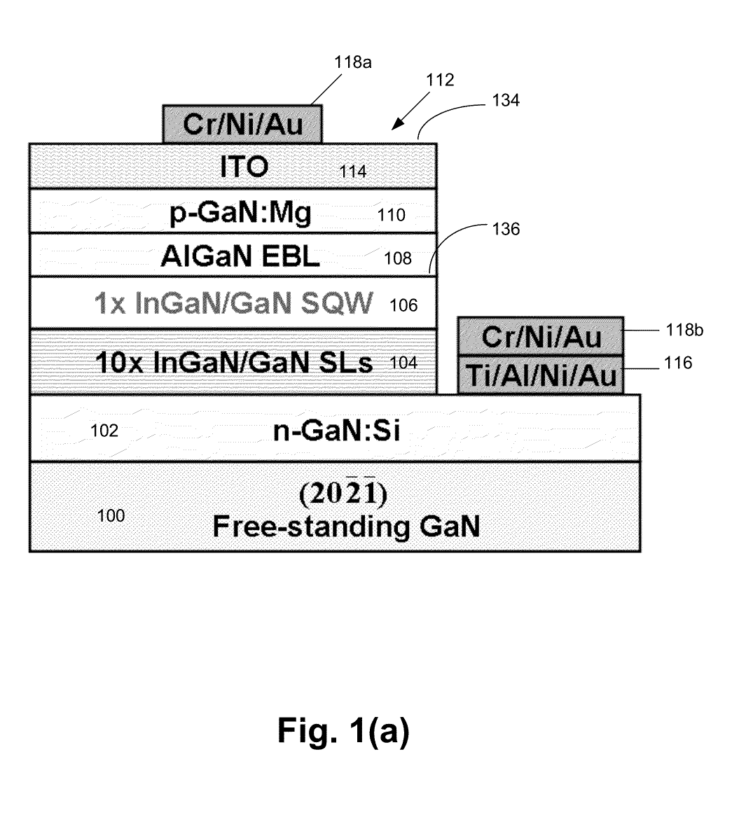

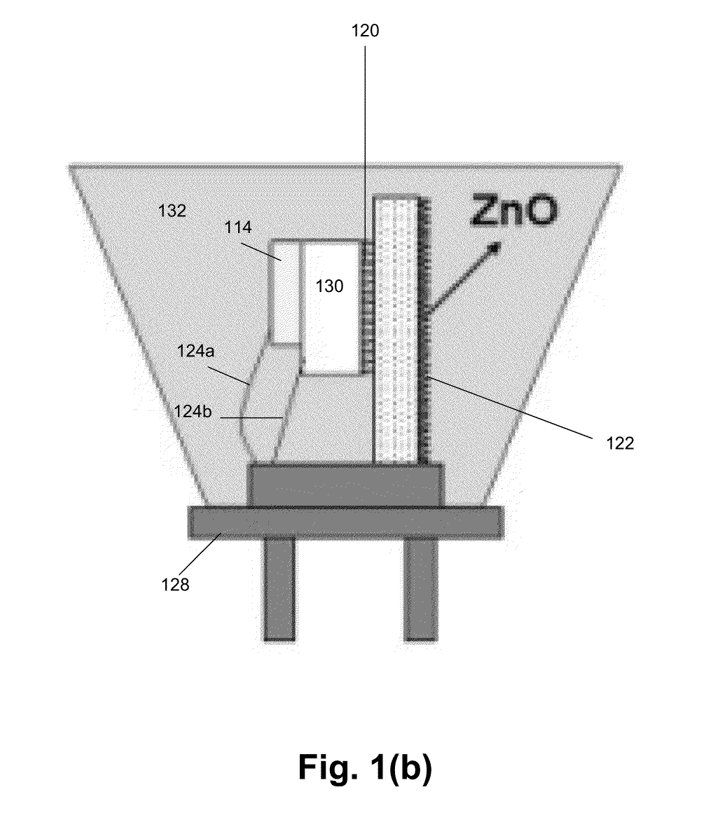

FIG. 1(a) shows a blue LED structure which was homoexpitaxially grown on a free-standing semipolar (20-2-1) GaN substrate 100 (having a 5×15 mm² surface area and a threading dislocation density of 10⁵-10⁶cm⁻²) using Metalorganic Chemical Vapor Deposition (MOCVD). The structure comprises a 1 micrometer (μm) thick Si-doped GaN layer 102 with a Silicon (Si) doping concentration of 1×10¹⁹ cm⁻³, followed by a 10 period In_{0.01}Ga_{0.99}N/GaN (3/3 nm) superlattice (SL) 104, followed by a GaN/InGaN/GaN single quantum well (SQW) active region 106 comprising a 10 nm thick GaN bottom barrier, a 12 nm thick In_{0.16}Ga_{0.82}N quantum well, and a 15 nm thick GaN upper barrier. The SQW/barrier layer was followed by a 3 nm thick electron blocking layer (EBL) 108 with a Magnesium (Mg) concentration of 2×10¹⁹ cm³ and a 50 nm thick p-type GaN layer 110 with an Mg concentration of 4×10¹⁹ cm³. Subsequently, small-area (0.1 mm²) mesas 112 were formed by chlorine-based reactive ion etching. A 250 nm thick indium-tin-oxide (ITO) layer 114 was deposited by electron beam evaporation as the transparent p-contact, and Ti/Al/Ni/Au (10/100/10/100 nm) layers 116 were deposited as the n-GaN contact. Finally, a thick Cr/Ni/Au metal stack (25/20/500 nm thickness respectively) was deposited on the ITO and the n-GaN contact, to serve as the p-side wire bond pad 118a and n-side wire-bond pad 118b.

The LEDs were grown on semipolar (20-2-1) free-standing GaN substrates by atmospheric pressure metal organic chemical vapor deposition (MOCVD). The typical growth temperature was ˜1000° C. for the n-type GaN layer, with a V/III ratio (the ratio of NH₃ mole fraction to Trimethyl-Gallium mole fraction) of 3000. The active region was grown at a temperature of ˜850° C. with a V/III ratio of 12000. The n-type superlattice is grown at 900° C. and the EBL and p-type layer are grown at 960° C. All MOCVD growth was performed at atmospheric pressure (AP).

FIG. 1(b) illustrates the roughened backside 120 of the substrate 100 attached to Zinc Oxide (ZnO), the ZnO having a roughened backside 122, gold wire bonds 124a, 124b electrically connecting the pads 118a, 118b to a silver header 126, and the ZnO standing on end on the header 128. The LED 130 and ZnO device is encapsulated in silicone 132.

Encapsulated devices with backside roughening and a Zinc Oxide (ZnO) vertical-stand package [7-8], as illustrated in FIG. 1(b), were tested in pulsed mode, with a 1 KHz repetition rate and pulse width of 20 μs (2% duty cycle) to prevent self-heating.

Reference [10] also describes an embodiment of the present invention.

Device characterization was performed at room temperature with forward currents up to 400 milliamps (mA).

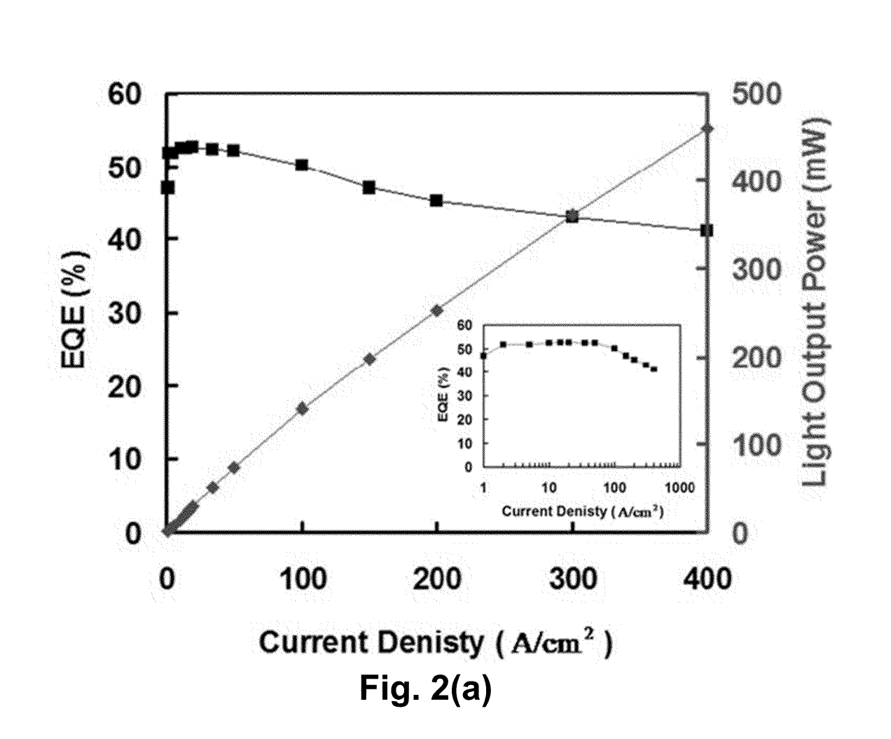

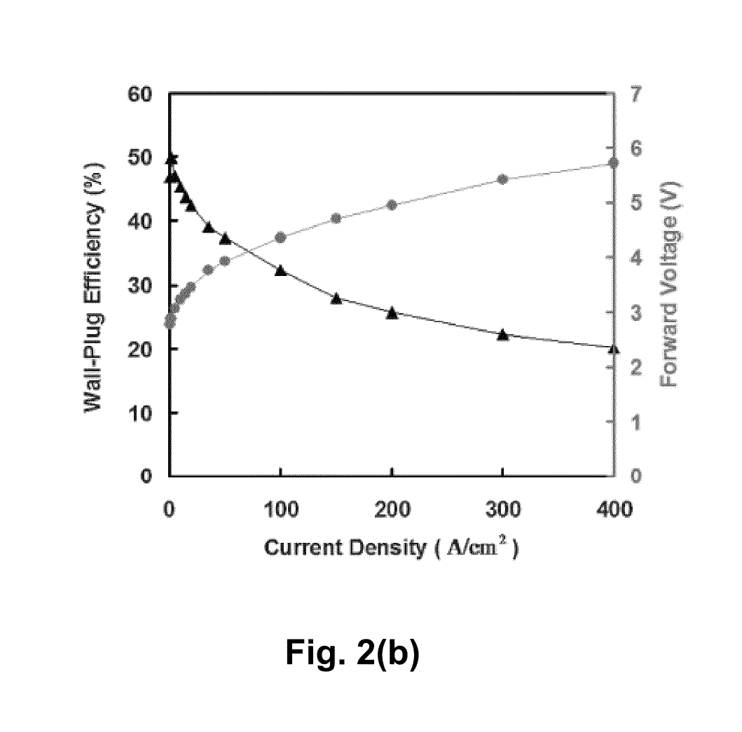

FIG. 2(a) shows the light output power (LOP) and external quantum efficiency (EQE) of the above described semipolar (20-2-1) LED, at different current densities up to 400 A/cm².

As seen in Table 1, the LED achieves EQEs of 50.1, 45.3, 43.0, and 41.2% at current densities of 100, 200, 300, and 400 A/cm², respectively. The corresponding LOPs are 140, 253, 361, and 460 mW at current densities of 100, 200, 300, and 400 A/cm², respectively. Under pulsed conditions, the corresponding EQE numbers and the efficiency droop at different current densities are also shown in Table 1. As can be seen in Table 1, an LED grown on the semipolar (20-2-1) plane has EQEs of 50.1, 45.3, 43.0, and 41.2% and LOPs of 140, 253, 361, and 460 mW at current densities of 100, 200, 300, and 400 A/cm², respectively.

TABLE 1
Light Output Powers and External Quantum Efficiencies
at different current densities.

| | | | | J = 400 |
|---|---|---|---|---|
| | J = 100 A/cm² | J = 200 A/cm² | J = 300 A/cm² | A/cm² |
| EQE (%) | 50.1 | 45.3 | 43.0 | 41.2 |
| LOP (mW) | 140 | 253 | 361 | 460 |

This large improvement in overall efficiency performance by growing LEDs on the semipolar (20-2-1) plane can be explained by the reduction in polarization related electric fields, the use of a SQW structure, and the use of a wide high-quality active region. All of the above can serve to lower the average carrier density in the device and mitigate the effects of both Auger recombination and carrier leakage.

FIG. 2(b) shows the wall plug efficiency of the above described semipolar LED.

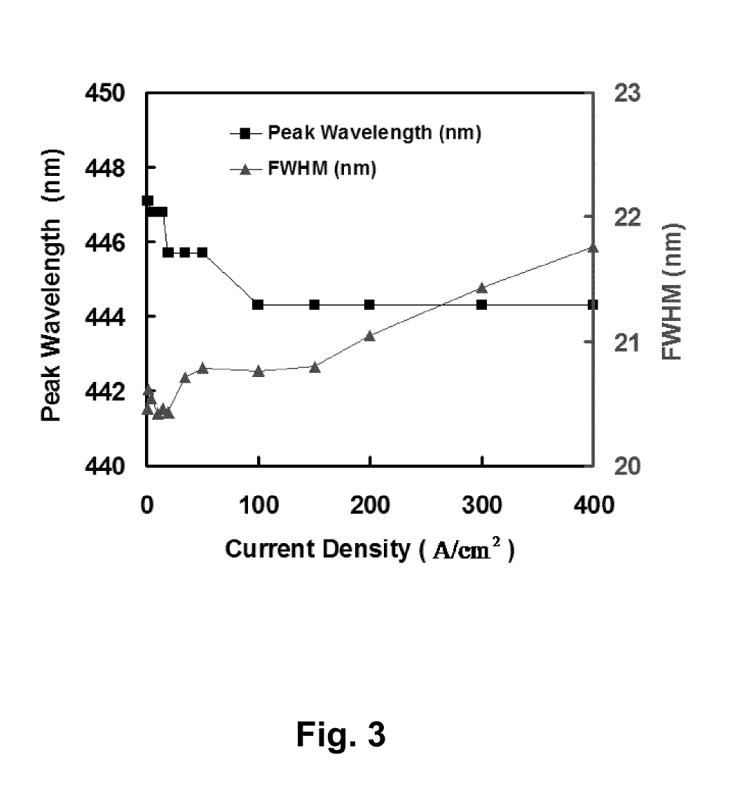

FIG. 3 shows the Full Width at Half Maximum (FWHM) and peak wavelength vs. current density for the semipolar (20-2-1) blue LED. As can be seen in FIG. 3, the semipolar (20-2-1) blue LED has a smaller FWHM than other semipolar LEDs and a smaller blue shift than LEDs grown on the conventional c-plane or other semipolar planes. While the minimal blue shift can be explained by the cancellation of the piezoelectric field and pn-junction built-in electric field components, the origin of the narrow FWHM is less clear. The semipolar (20-2-1) plane shows a high indium incorporation rate compared to other planes, allowing for an increase in the QW growth temperature required to achieve a given emission wavelength. In the blue wavelength regime, or for the same target emission wavelength, the growth temperature of the (20-2-1) device can be increased by ˜35° C. as compared to the growth temperature of a (20-21) device. Typically, increased growth temperatures result in improved crystal quality, which may explain the narrow FWHM values for the semipolar (20-2-1) Quantum Well (QW). This may also result in a QW with more uniform InGaN and fewer QW thickness variations. Consequently, an InGaN QW on the semipolar (20-2-1) plane may exhibit fewer potential fluctuations than an InGaN QW on c-plane, resulting in a lower degree of carrier localization and a reduction in the band filling of localized states, which is one proposed origin for efficiency droop.

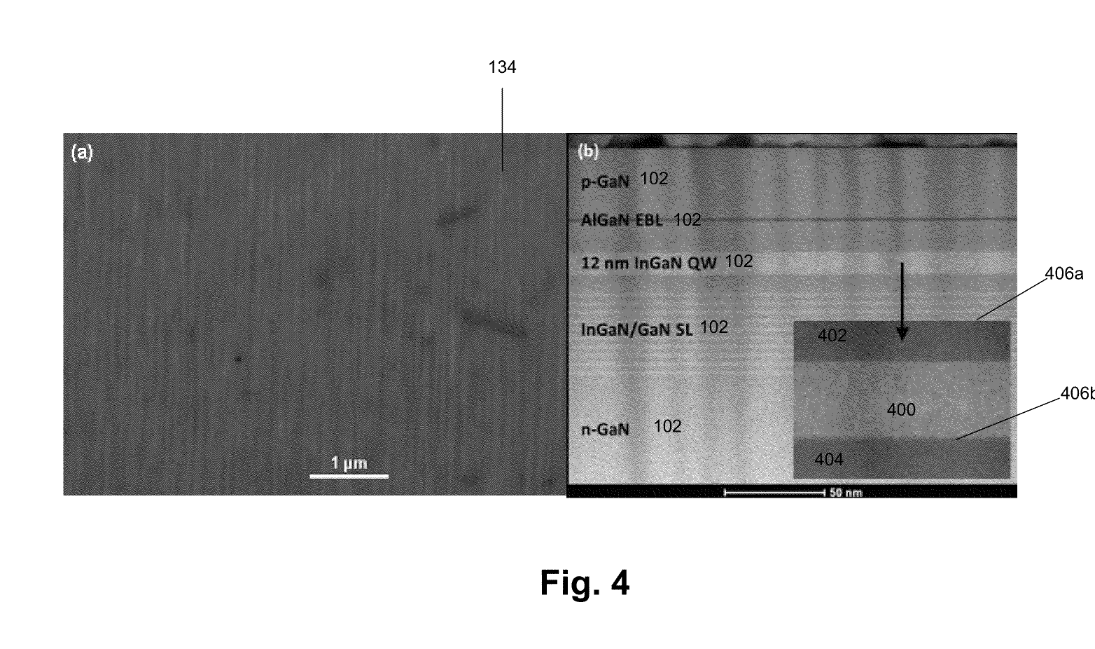

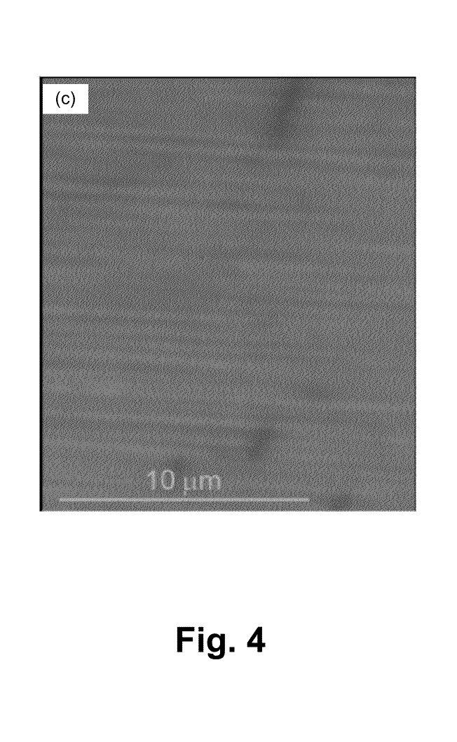

FIGS. 4(a) and 4(c) are μ-EL images of the top surface 134 of the ITO layer 114. These images are uniform as compared to a c-plane device. FIG. 4(b) is a cross-sectional STEM image of the structure of FIG. 1(a), also showing a close up of the active region comprising an InGaN QW 400 with GaN barriers 402, 404 and QW interfaces 406a, 406b. Focusing on the SQW region, FIG. 4(b) shows a uniform QW and clear interfaces.

Based on the small blue-shift and narrow spectral width shown in FIG. 3, and the μ-EL and STEM images in FIG. 4 showing uniform QW emission and smooth QW interfaces 406a-b, the present invention proposes that InGaN QWs on the semipolar (20-2-1) plane are relatively free from potential fluctuations. This results in a low degree of carrier localization and minimal band filling of localized states. Ryu et. al. [9] recently postulated that polarization related-electric fields, non-uniform carrier distribution, and potential fluctuations significantly reduce the effective active region volume over which carriers are distributed in conventional c-plane InGaN QWs. As a result, high carrier densities are present in the active region, which exacerbates the effects of Auger recombination and carrier leakage, resulting in efficiency droop. In the present invention's semipolar (20-2-1) LEDs, polarization-related electric fields are significantly reduced, a SQW active region eliminates carrier non-uniformity issues, and a wide high-quality InGaN layer reduces the effects of potential fluctuations and lowers the average carrier density. This reduces the effects of Auger recombination and carrier leakage, resulting in a device with low efficiency droop.

Process Steps

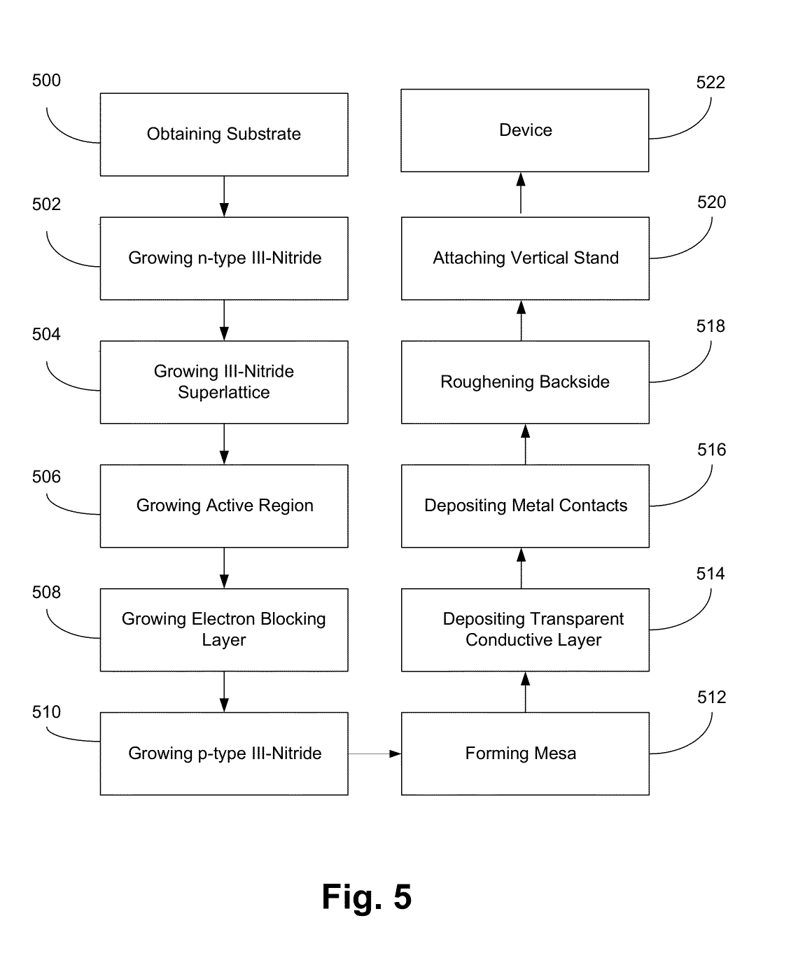

FIG. 5 illustrates a method of fabricating a III-nitride based semipolar LED having a light output power of at least 100 mW and/or an EQE of at least 50%, at a current density of at least 100 A/cm². The method can comprise the following steps (referring also to FIG. 1(a) and FIG. 1(b)).

Block 500 represents obtaining a substrate, such as a III-nitride (e.g., GaN) substrate or III-nitride/GaN template on a substrate. The device or LED can be grown on a semipolar plane, e.g., 20-2-1 plane, of the III-nitride substrate or template. The substrate can be a bulk or free standing substrate, such as free standing (20-2-1) GaN substrate 100. The III-nitride or GaN substrate can have a threading dislocation density less than 10⁶ cm⁻² for example.

Block 502 represents growing an n-type III-nitride (e.g., GaN 102) layer on or above or overlying a semipolar plane of the GaN substrate.

Block 504 represents growing a III-nitride superlattice (e.g., an InGaN/GaN superlattice 104) on or above or overlying the n-type III-nitride layer. The superlattice can act as a strain compensation layer reducing the threading dislocation density.

Block 506 represents growing a semipolar active region (e.g., InGaN/GaN SQW or InGaN quantum well with GaN barriers 106) on or above or overlying the superlattice.

Selecting the active region structure (e.g., the use of a single quantum well) can provide carrier uniformity (e.g., increase uniformity of the distribution of carriers, such as electrons, in the active region, as illustrated in FIG. 4), and selecting the active region thickness (e.g., using a larger thickness for the active region or quantum well, e.g., above 4 nm) can reduce the carrier density. A quantum well thickness of each QW or the SQW can be thicker than 4 nm, for example.

However, one or more embodiments of the invention could use the structure having a number of quantum wells (multi quantum well structure) if the desired EQE and/or LOP is obtained.

The active region can be such that a peak wavelength of the light emitted by the active region in response to the current density is in a blue spectrum or wavelength range (e.g., the active region can have a thickness, quantum well thickness, and composition, e.g., Indium composition, such that a peak wavelength of the light is in a blue spectrum or wavelength range). However, the active region can also emit light having peak wavelengths corresponding to other colors.

Block 508 represents growing an EBL (e.g., AlGaN 108) on or above or overlying the active region.

Block 510 represents growing a p-type III-nitride (e.g., GaN 110) layer on or above or overlying the EBL.

Block 512 represents forming a mesa 134 in the device layers 104-110. A top surface area of the mesa 134, or a top surface 136 of the light emitting active region 106 of the LED, can be less than 1 mm², less than 0.2 mm², or no more than 0.1 mm².

Block 514 represents depositing a transparent conductive contact layer (e.g., ITO 114) on or above or overlying the p-type III-nitride layer.

Block 516 represents depositing metal contacts on the n-type III-nitride layer and the transparent conductive contact layer.

Block 518 represents roughening a backside of the substrate.

Block 520 represents attaching the backside of the substrate to a transparent support, stand, light extraction medium, submount or substrate, such as a ZnO vertical stand package and roughening a surface of the ZnO [7,8] illustrated in FIG. 1(b).

Block 522 represents the end result, a III-nitride based LED, comprising a III-nitride based semipolar LED with a light output power of at least 100 mW and/or with an EQE of at least 50%, at a current density of at least 100 A/cm². A wavelength shift of the peak wavelength can be less than 4 nm up to a current density of 400 A/cm². The output power can be more than 140 mW at the current density of 100 A/cm² or more than 460 mW at the current density of 400 A/cm². The EQE drop can be less than 9% when the current density is changed from 100 to 400 A/cm². For example,

EQE droop (%)=100×((EQEₚₑₐₖ−EQE(current density))/EQEₚₑₐₖ can be 0.7, 5.1. 14.1. 18.4. and 21.9% at J=35, 100, 200, 300, and 400 A/cm², respectively, where EQE peak is the peak EQE and EQE(current density) is the EQE at the current density J.

The present invention has shown that the above unexpected and significantly improved output power, wavelength shift, and EQE can be obtained by selection of a combination of the layers/substrate/regions fabricated/obtained in one or more of Blocks 500-522. Specifically, the layers/substrate/regions fabricated/obtained in Blocks 500-518 can have a crystal quality (e.g., selection of substrate, threading dislocation density, semipolar plane or orientation and/or growth conditions) and structure (e.g., selection of an active region thickness, selection of a number of quantum wells such as a SQW, selection of a superlattice having a number of periods and a composition) such that the LED emits light with the above described significantly improved output power, wavelength shift, and EQE (see also FIG. 2 and FIG. 3).

In one embodiment, the selection includes an n-type GaN layer 102 overlying a semipolar plane (e.g., 20-2-1) of a bulk GaN substrate 100; a superlattice 104 comprising an

InGaN/GaN superlattice 104 overlying the n-type GaN layer 102; an InGaN/GaN SQW 106 overlying the InGaN/GaN superlattice 104, wherein increasing the SQW thickness (e.g., above 4 nm) reduces carrier density and selecting the SQW increases a uniformity of the distribution of carriers (e.g., electrons) in the active region; an AlGaN EBL 108 overlying the SQW; a p-type GaN layer 110 overlying the EBL; a transparent conductive contact layer 114 overlying the p-type GaN layer 110; metal contact 116 to the n-type GaN layer 102, and a ZnO (or transparent light extraction) vertical stand package attached to the roughened backside of the GaN substrate 100.

However, this is just one example of a selection or combination. The above output power, EQE, and wavelength shift could be achieved with other selections or combinations, or different combinations of one or more of the features or layers described in Blocks 500-520.

Possible Modifications and Variations

Device performance can be improved by optimizing the structure, e.g., using multi-quantum wells (MQWs), compositionally step-graded InGaN barriers, etc., of semipolar (20-2-1) blue LEDs. The LED can be a blue LED emitting blue light, or an LED emitting other wavelengths of light. Other semipolar planes or orientations could also be used.

The present invention can be applied to other optoelectronic devices, such as in a Laser or Laser Diode structure, solar cell, or transistor.

Advantages and Improvements

Due to the power roll-over observed in polar c-plane LEDs at high current densities, large-area (˜1 mm²) chips are typically required in high-power applications to reduce the average operating current density and mitigate the effects of efficiency droop. Alternatively, achieving high-efficiency and low-droop operation at high current densities (>100 A/cm²) would allow for the implementation of small-area (˜0.1 mm²) chips in high-power applications. This approach would reduce the device footprint and ultimately lead to cost reductions. Additionally, small-area devices better approximate a point source geometry, which provides advantages for tailoring light-output directionality and simplifies associated optics.

LEDs grown on nonpolar and semipolar orientations have negligible or reduced polarization-related electric fields and are expected to have higher radiative recombination rates than c-plane LEDs.

The present invention demonstrates that a wide (>4 nanometer (nm)) single-quantum well (SQW) active region on a semipolar plane of Gallium Nitride (GaN) results in very high efficiency LEDs with very low efficiency droop. The semipolar plane results in reduced polarization-related electric fields and increases the radiative efficiency of the device, the SQW structure prevents carrier non-uniformity issues, and the wide high-quality active region reduces the average operating carrier density in the device. The combination of these effects leads to devices with very low efficiency droop.

More specifically, in one example, a 12 nm thick single-quantum-well for a blue LED (chip size=0.1 mm²) was grown on the semipolar (20-2-1) plane (packaged with a novel transparent vertical geometry ZnO stand) and achieved external quantum efficiencies (EQEs) of 50.1, 45.3, 43.0, and 41.2%, and light output powers (LOPs) of 140, 253, 361, and 460 mW at current densities of 100, 200, 300, and 400 A/cm², respectively, under pulsed (2% duty cycle) operation. The present invention also observed a small blue shift of ˜3 nm and a full-width at half-maximum (FWHM) of only ˜20.5-21.7 nm for the semipolar SQW blue LED, with increasing current density up to 400 A/cm².

### REFERENCES

The following references are incorporated by reference herein.

[1] Kwang-Choong Kim et. al., “Study of nonpolar m-plane . . . , ” Appl. Phys. Lett. 91 (2007) 181120.

[2] Yuji Zhao et. al., “High-Power Blue-Violet Semipolar (20-2-1) . . . , ” Appl. Phys. Express 4 (2011) 082104.

[3] Yuji Zhao et. al., “30-mW-Class High-Power and High-Efficiency . . . , ” Appl. Phys. Express 3 (2010) 102101.

[4] S. Yamamoto et. al., “High-Efficiency Single-Quantum-Well . . . , ” Appl. Phys. Express 3 (2010) 122102.

[5] Chia-Yen Huang et. al., “Demonstration of 505 nm laser diodes . . . , ” Appl. Phys. Lett., 99, 241115 (2011).

[6] U.S. Pat. No. 7,968,864 issued Jun. 28, 2011.

[7] Yuji Zhao, Junichi Sonoda, Chih-Chien Pan, Stuart Brinkley, Ingrid Koslow, Kenji Fujito, Hiroaki Ohta, Steven P. DenBaars, and Shuji Nakamura: Appl. Phys. Express 3 (2010) 102101.

[8] Chih-Chien Pan, Ingrid Koslow, Junichi Sonoda, Hiroaki Ohta, Jun-Seok Ha, Shuji Nakamura, and Steven P. DenBaars: Jpn. J. Appl. Phys. 49 (2010) 080210.

[9] Han-Youl Ryu, Dong-Soo Shin, and Jong-In Shim, Appl. Phys. Lett., 100, 131109 (2012).

[10] “High-Power, Low-Efficiency-droop Semipolar (20-2-1) Single-Quantum-Well Blue Light-Emitting Diodes,” by Chih-Chien Pan, Shinichi Tanaka, Feng Wu, Yuji Zhao, James S. Speck, Shuji Nakamura, Steven P. DenBaars, and Daniel Feezell, Appl. Physics Express 5 (2012), 062103-1.

[11] High-Power, Low-Efficiency Droop Semipolar (20-2-1) Single-Quantum-Well Blue Light Emitting Diodes” by Chih-Chien Pan, Shinichi Tanaka, Feng Wu, Yuji Zhao, James S. Speck, Shuji Nakamura, Steven P. DenBaars, and Daniel Feezell, conference abstract submitted to International Symposium on Semiconductor Light Emitting Devices (ISSLED), conference dates Jul. 22 to 27, 2012.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A III-nitride based Light Emitting Diode (LED), comprising:
a III-nitride based semipolar LED with a light output power of at least 100 milliwatts (mW), or with an External Quantum Efficiency (EQE) of at least 50%, at a current density of at least 100 Amps per centimeter square (A/cm²).

2. The LED of claim 1, wherein the LED is a semipolar LED grown on a bulk Gallium Nitride substrate or semipolar Gallium Nitride (GaN).

3. The LED of claim 2, further comprising an active region for emitting the light, wherein the active region comprises one or more quantum wells having a thickness of at least 4 nanometers.

4. The LED of claim 3, wherein the LED is grown on a semipolar plane of the GaN and the semipolar plane is (20-2-1).

5. The LED of claim 3, wherein the active region comprises one quantum well or a single quantum well (SQW).

6. The LED of claim 1, wherein a peak wavelength of the light is in a blue spectrum or wavelength range.

7. The LED of claim 6, wherein a wavelength shift of the peak wavelength is less than 4 nm up to a current density of 400 A/cm².

8. The LED of claim 1, wherein a top surface area of the LED, or a top surface of the light emitting active region of the LED, is less than 0.2 mm².

9. The LED of claim 8, wherein the output power is more than 140 mW at the current density of 100 A/cm² or more than 460 mW at the current density of 400 A/cm².

10. The LED of claim 1, wherein the EQE drop is less than 9% when the current density is changed from 100 to 400 A/cm².

11. The LED of claim 1, wherein the III-nitride based semipolar Light Emitting Diode (LED) the LED has a crystal quality, active region thickness, semipolar orientation, and structure such that the light output power is at least 100 mW, or the EQE is at least 50%, at the current density of at least 100 A/cm².

12. The LED of claim 11, wherein the structure increases carrier uniformity, the active region thickness reduces the carrier density, and the semipolar orientation of the LED increases the crystal quality such that the output power or the EQE is obtained.

13. The LED of claim 12, wherein the structure includes a number of quantum wells in the active region.

14. The LED of claim 11, wherein the structure includes a superlattice between the substrate and an active region of the LED, wherein the superlattice has a number of periods and composition such that the light output power is at least 100 mW, or the EQE is at least 50%, for the current density of at least 100 A/cm².

15. The LED of claim 14, wherein the LED further comprises:
a GaN substrate;
an n-type GaN layer overlying a semipolar plane of the GaN substrate;
the superlattice comprising an InGaN/GaN superlattice overlying the n-type GaN layer;
the active region including an InGaN/GaN single quantum well overlying the InGaN/GaN superlattice;
an AlGaN electron blocking layer overlying the single quantum well;
a p-type GaN layer overlying the electron blocking layer;
a transparent conductive contact layer overlying the p-type GaN layer; and
metal contact to the n-type GaN layer.

16. A method of fabricating a device, comprising:
fabricating a III-nitride based semipolar Light Emitting Diode (LED) having a light output power of at least 100 milliwatts (mW), or an External Quantum Efficiency (EQE) of at least 50%, at a current density of at least 100 Amps per centimeter square (A/cm²).

17. The method of claim 16, wherein the fabricating comprises growing the LED under growth conditions and with a crystal quality, active region thickness, semipolar orientation, and structure wherein the III-nitride based semipolar LED has a light output power of at least 100 milliwatts (mW), or an External Quantum Efficiency (EQE) of at least 50%, for a current density of at least 100 Amps per centimeter square (A/cm²).

18. The method of claim 18, wherein the LED is a semipolar LED grown on a semipolar plane of a bulk Gallium Nitride (GaN) substrate or on semipolar GaN.

19. The method of claim 18, wherein:
the semipolar plane is (20-2-1), and
an active region in the LED for emitting the light is a single quantum well (SQW).
